(19) United States
(12) Patent Application Publication
(10) Pub. No.: US 2010/0021657 A1
(43) Pub. Date: Jan. 28, 2010

(54) PROCESS FOR PRODUCING ELECTRICALLY CONDUCTIVE SURFACES

(75) Inventors: Rene Lochtman, Mannheim (DE); Jürgen Kaczun, Wachenheim (DE); Norbert Wagner, Mutterstadt (DE); Jürgen Pfister, Speyer (DE)

Correspondence Address: CONNOLLY BOVE LODGE & HUTZ, LLP, P O BOX 2207, WILMINGTON, DE, 19899, US

(73) Assignee: BASF SE, Ludwigshafen (DE)

(21) Appl. No.: 12/522,026

(22) PCT Filed: Dec. 21, 2007
(86) PCT No.: PCT/EP07/64413

§ 371 Date: Jul. 2, 2009

(30) Foreign Application Priority Data
Jan. 5, 2007 (EP) 07100159.8

(51) Int. Cl. H05K 3/24; C25D 5/54

(52) U.S. Cl. 427/597; 427/596; 205/122

(57) ABSTRACT

The invention relates to a method for producing electrically conductive surfaces on a nonconductive substrate, comprising the following steps:
a) transferring a dispersion containing electrolessly and/or electrolytically coatable particles from a support onto the substrate by irradiating the support with a laser,
b) at least partially drying and/or curing the dispersion transferred onto the substrate, so as to form a base layer,
c) electrolessly and/or electrolytically coating the base layer.

The invention relates to a method for producing electrically conductive surfaces on a nonconductive substrate.

The method according to the invention is suitable, for example, for producing conductor tracks on printed circuit boards, RFID antennas, transponder antennas or other antenna structures, chip card modules, flat cables, seat heaters, foil conductors, conductor tracks in solar cells or in LCD/plasma screens, integrated circuits, resistive, capacitive or inductive elements, diodes, transistors, sensors, actuators, optical components, receiver/transmitter devices, decorative or functional surfaces on products, which are used for shielding electromagnetic radiation, for thermal conduction or as packaging, thin metal foils or polymer supports clad on one or two sides. Electrolytically coated products in any form may also be produced by the method.

A method for producing electrically conductive surfaces on a substrate is known, for example, from U.S. Pat. No. 6,177,151. Electrically conductive particles, which are contained in a matrix material, are in this case transferred from a support onto the substrate. The transfer is carried out by irradiation with a laser. The laser liquefies the matrix material, so that the transfer material is transferred onto the substrate. The transfer material and the matrix material initially form a solid coating on the support. If the melting point of the matrix material lies below ambient temperature, freezing of the support with the matrix material is described so that the matrix material becomes solid.

WO 99/44402 likewise discloses a method for producing electrically conductive surfaces on a substrate. A support, onto which the coating material is applied, is in this case brought in contact with a substrate or into the vicinity of the substrate. The coating material is melted by a laser beam, and the molten material is transferred onto the substrate. A large energy input is required in this case, so that the entire coating material is melted.

A disadvantage of both methods is that the structures thereby produced on the substrate do not have a continuous electrically conductive surface. In order to generate electrically conductive structures, it is therefore necessary to transfer a large amount of electrically conductive material or select a correspondingly large layer thickness, so that a continuous electrically conductive structure is obtained.

A device for printing on a substrate is described, for example, in DE-A 37 02 643. Printing ink is in this case applied onto an ink film running around a plurality of rollers. The printing ink is heated with the aid of a laser. This creates a gas bubble, which becomes progressively larger and then bursts under its pressure. Ink droplets are thereby projected against the substrate. An electrically conductive surface, however, cannot be generated by this method.

Further disadvantages of the methods known from the prior art are the poor adhesion and lack of homogeneity and continuity of the transferred layer. This is generally attributable to the fact that the transferred materials, which are intended to generate the conductor tracks, comprise interruptions or short circuits in their conductor track structure. Embedding in matrix material is problematic above all when using very small particles (particles in the micro- to nanometer range). An oxide layer present on the electrically conductive particles will exacerbate this effect even further. A homogeneous, continuous metal coating can therefore be produced only with great difficulty or not at all, so that there is no process reliability.

It is an object of the invention to provide an alternative method, by which electrically conductive structured or full-area surfaces can be produced on a support, these surfaces being homogeneous and continuously electrically conductive.

The object is achieved by a method for producing electrically conductive surfaces on a nonconductive substrate, comprising the following steps:
a) transferring a dispersion containing electrolessly and/or electrolytically coatable particles from a support onto the substrate by irradiating the support with a laser,
b) at least partially drying, and/or curing the dispersion transferred onto the substrate, so as to form a base layer,
c) electrolessly and/or electrolytically coating the base layer.

Rigid or flexible supports, for example, are suitable as supports onto which the electrically conductive surface is applied. The support is preferably electrically nonconductive. This means that the resistivity is more than 10⁹ ohm×cm. Suitable supports are for example reinforced or unreinforced polymers, such as those conventionally used for printed circuit boards. Suitable polymers are epoxy resins or modified epoxy resins, for example bifunctional or polyfunctional Bisphenol A or Bisphenol F resins, epoxy-novolak resins, brominated epoxy resins, aramid-reinforced or glass fiber-reinforced or paper-reinforced epoxy resins (for example FR4), glass fiber-reinforced plastics, liquid-crystal polymers (LCP), polyphenylene sulfides (PPS), polyoxymethylenes (POM), polyaryl ether ketones (PAEK), polyether ether ketones (PEEK), polyamides (PA), polycarbonates (PC), polybutylene terephthalates (PBT), polyethylene terephthalates (PET), polyimides (PI), polyimide resins, cyanate esters, bismaleimide-triazine resins, nylon, vinyl ester resins, polyesters, polyester resins, polyamides, polyanilines, phenol resins, polypyrroles, polyethylene naphthalate (PEN), polymethyl methacrylate, polyethylene dioxithiophene, phenolic resin-coated aramid paper, polytetrafluoroethylene (PTFE), melamine resins, silicone resins, fluorine resins, allylated polyphenylene ethers (APPE), polyether imides (PEI), polyphenylene oxides (PPO), polypropylenes (PP), polyethylenes (PE), polysulfones (PSU), polyether sulfones (PES), polyaryl amides (PAA), polyvinyl chlorides (PVC), polystyrenes (PS), acrylonitrile-butadiene-styrene (ABS), acrylonitrile-styrene acrylate (ASA), styrene acrylonitrile (SAN) and mixtures (blends) of two or more of the aforementioned polymers, which may be present in a wide variety of forms. The substrates may comprise additives known to the person skilled in the art, for example flame retardants.

In principle, all polymers mentioned below in respect of the matrix material may also be used. Other substrates likewise conventional in the printed circuit industry are also suitable.

Composite materials, foam-like polymers, Styropor®, Styrodur®, polyurethanes (PU), ceramic surfaces, textiles, pulp, board, paper, polymer-coated paper, wood, mineral materials, silicon, glass, vegetable tissue and animal tissue are furthermore suitable substrates.

In a first step, a dispersion which contains electrolessly and/or electrolytically coatable particles is transferred from a support onto the substrate. The transfer is carried out by irradiating the dispersion on the support with a laser.

Before the dispersion with the electrolessly and/or electrolytically coatable particles contained therein is transferred, it is preferably applied surface-wide on the support. As an alternative, it is of course also possible for the dispersion to be applied onto the support in a structured way. Surface-wide application of the dispersion, however, is preferred.

All materials transparent for the laser radiation in question are suitable as a support, for example plastic or glass. When IR lasers are employed, for example, it is thus possible to use polyolefin sheets, PET sheets, polyimide sheets, polyamide sheets, PEN sheets, polystyrene sheets, or glass.

The substrate may be either rigid or flexible. The support may furthermore be in the form of a hose or endless sheet, sleeve or as a flat support.

Suitable laser beam sources for generating the laser beam are commercially available. All laser beam sources may in principle be used. Such laser beam sources are for example pulsed or continuous wave gas, solid state, diode or excimer lasers. These may respectively be used so long as the support in question is transparent for the laser radiation and the dispersion, which contains the electrolessly and/or electrolytically coatable particles and is applied on the support, absorbs the laser radiation sufficiently in order to generate a cavitation bubble on the base layer by converting light energy into heat energy.

Pulsed or continuous wave (cw) IR lasers are preferably used as the laser source, for example Nd-YAG lasers, Yb:YAG lasers, fiber or diode lasers. These are available inexpensively and with high power. Continuous wave (cw) IR lasers are particularly preferred. As a function of the absorptivity of the dispersion which contains the electrolessly and/or electrolytically coatable particles, however, it is also possible to use lasers with wavelengths in the visible or UV frequency range. Suitable for this, for example, are Ar lasers, HeNe lasers, frequency-multiplied solid state IR lasers or excimer lasers, such as ArF lasers, KrF lasers, XeCl lasers or XeF lasers. As a function of the laser beam source, the laser power and the optics and modulators used, the focal diameter of the laser beam lies in the range of between 1 μm and 100 μm. In order to generate the structure of the surface, it is also possible to arrange a mask in the beam path of the laser or employ an imaging method known to the person skilled in the art.

In a preferred embodiment, the desired parts of the dispersion applied onto the support and containing the electrolessly and/or electrolytically coatable particles are transferred onto the substrate by means of a laser focused onto the dispersion.

In order to carry out the method according to the invention, the laser beam and/or the support and/or the substrate may be moved. The laser beam may, for example, be moved by optics known to the person skilled in the art having rotating mirrors. The support may, for example, be configured as a revolving endless sheet which is coated continuously with the dispersion containing the electrolessly and/or electrolytically coatable particles. The substrate may, for example, be moved by means of an XY stage or as an endless sheet with an unwinding and winding device.

An advantage of the method according to the invention is that besides two-dimensional circuit structures, for example, it is also possible to produce three-dimensional circuit structures, for example 3D molded interconnected devices. It is also possible to provide the interior of device packages with conductor tracks having an extremely fine structure. When producing three-dimensional objects, for example, each surface may be processed in succession either by bringing the object into the correct position, or by appropriately steering the laser beam.

The dispersion, which is transferred from the support onto the substrate, generally contains electrolessly and/or electrolytically coatable particles in a matrix material. The electrolessly and/or electrolytically coatable particles may be particles of arbitrary geometry made of any electrically conductive material, mixtures of different electrically conductive materials or else mixtures of electrically conductive and nonconductive materials. Suitable electrically conductive materials are for example carbon, such as carbon black, graphite, graphenes or carbon nanotubes, electrically conductive metal complexes, conductive organic compounds or conductive polymers or metals. Zinc, nickel, copper, tin, cobalt, manganese, iron, magnesium, lead, chromium, bismuth, silver, gold, aluminum, titanium, palladium, platinum, tantalum and alloys thereof are preferred, or metal mixtures which contain at least one of these metals. Suitable alloys are for example CuZn, CuSn, CuNi, SnPb, SnBi, SnCo, NiPb, ZnFe, ZnNi, ZnCo and ZnMn. Aluminum, iron, copper, nickel, zinc, carbon and mixtures thereof are particularly preferred.

The electrolessly and/or electrolytically coatable particles preferably have an average particle diameter of from 0.001 to 100 μm, preferably from 0.005 to 50 μm and particularly preferably from 0.01 to 10 μm. The average particle diameter may be determined by means of laser diffraction measurement, for example using a Microtrac X100 device. The distribution of the particle diameters depends on their production method. The diameter distribution typically comprises only one maximum, although a plurality of maxima are also possible.

The surface of the electrolessly and/or electrolytically coatable particles may be provided at least partially with a coating. Suitable coatings may be inorganic or organic in nature. Inorganic coatings are, for example SiO₂, phosphates, or phosphides. The electrolessly and/or electrolytically coatable particles may of course also be coated with a metal or metal oxide. The metal may likewise be present in a partially oxidized form.

If two or more different metals are intended to form the electrolessly and/or electrolytically coatable particles, then this may be done using a mixture of these metals. It is particularly preferable for the metal to be selected from the group consisting of aluminum, iron, copper, nickel and zinc.

The electrolessly and/or electrolytically coatable particles may nevertheless also contain a first metal and a second metal, the second metal being present in the form of an alloy with the first metal or one or more other metals, or the electrolessly and/or electrolytically coatable particles contain two different alloys.

Besides the choice of electrolessly and/or electrolytically coatable particles, the shape of the electrical conductive particles also has an effect on the properties of the dispersion after coating. In respect of the shape, numerous variants known to the person skilled in the art are possible. The shape of the electrolessly and/or electrolytically coatable particles may, for example, be needle-shaped, cylindrical, platelet-shaped or spherical. These particle shapes represent idealized shapes and the actual shape may differ more or less strongly therefrom, for example owing to production. For example, teardrop-shaped particles are a real deviation from the idealized spherical shape in the scope of the present invention.

Electrolessly and/or electrolytically coatable particles with various particle shapes are commercially available.

When mixtures of electrolessly and/or electrolytically coatable particles are used, the individual mixing partners may also have different particle shapes and/or particle sizes. It is also possible to use mixtures of only one type of electrolessly and/or electrolytically coatable particles with different particle sizes and/or particle shapes. In the case of different particle shapes and/or particle sizes, the metals aluminum, iron, copper, nickel and zinc as well as carbon are likewise preferred.

When mixtures of particle shapes are used, mixtures of spherical particles with platelet-shaped particles are preferred. In one embodiment, for example, spherical carbonyl-iron particles are used with platelet-shaped iron and/or copper particles and/or carbon particles of different geometries.

As already mentioned above, the electrolessly and/or electrolytically coatable particles may be added to the dispersion in the form of their powder. Such powders, for example metal powder, are commercially available goods or can readily be produced by means of known methods, for instance by electrolytic deposition or chemical reduction from solutions of metal salts or by reduction of an oxidic powder, for example by means of hydrogen, by spraying or atomizing a metal melt, particularly into coolants, for example gases or water. Gas and water atomization and the reduction of metal oxides are preferred. Metal powders with the preferred particle size may also be produced by grinding coarser metal powder. A ball mill, for example, is suitable for this. Besides gas and water atomization, the carbonyl-iron powder process for producing carbonyl-iron powder is preferred in the case of iron. This is done by thermal decomposition of iron pentacarbonyl. This is described, for example, in Ullman's Encyclopedia of Industrial Chemistry, 5th Edition, Vol. A14, p. 599. The decomposition of iron pentacarbonyl may, for example, take place at elevated temperatures and elevated pressures in a heatable decomposer that comprises a tube of a refractory material such as quartz glass or V2A steel in a preferably vertical position, which is enclosed by a heating instrument, for example consisting of heating baths, heating wires or a heating jacket through which a heating medium flows.

According to a similar method, carbonyl-nickel powder may also be used.

Platelet-shaped electrolessly and/or electrolytically coatable particles can be controlled by optimized conditions in the production process or obtained afterwards by mechanical treatment, for example by treatment in an agitator ball mill.

Expressed in terms of the total weight of the dried coating, the proportion of electrolessly and/or electrolytically coatable particles preferably lies in the range of from 20 to 98 wt. %. A preferred range for the proportion of the electrolessly and/or electrolytically coatable particles is from 30 to 95 wt. % expressed in terms of the total weight of the dried coating.

For example, binders with a pigment-affine anchor group, natural and synthetic polymers and derivatives thereof, natural resins as well as synthetic resins and derivatives thereof, natural rubber, synthetic rubber, proteins, cellulose derivatives, drying and non-drying oils etc. are suitable as a matrix material. They may—but need not—be chemically or physically curing, for example air-curing, radiation-curing or temperature-curing.

The matrix material is preferably a polymer or polymer blend.

Polymers preferred as a matrix material are, for example, ABS (acrylonitrile-butadiene-styrene); ASA (acrylonitrile-styrene acrylate); acrylic acrylates; alkyd resins; alkyl vinyl acetates; alkyl vinyl acetate copolymers, in particular methylene vinyl acetate, ethylene vinyl acetate, butylene vinyl acetate; alkylene vinyl chloride copolymers; amino resins; aldehyde and ketone resins; celluloses and cellulose derivatives, in particular hydroxyalkyl celluloses, cellulose esters such as acetates, propionates, butyrates, carboxyalkyl celluloses, cellulose nitrate; epoxy acrylate; epoxy resins; modified epoxy resins, for example bifunctional or polyfunctional Bisphenol A or Bisphenol F resins, epoxy-novolak resins, brominated epoxy resins, cycloaliphatic epoxy resins; aliphatic epoxy resins, glycidyl ethers, vinyl ethers, ethylene-acrylic acid copolymers; hydrocarbon resins; MABS (transparent ABS also containing acrylate units); melamine resins, maleic acid anhydride copolymers; methacrylates; natural rubber; synthetic rubber; chlorine rubber; natural resins; colophonium resins; shellac; phenolic resins; polyesters; polyester resins such as phenyl ester resins; polysulfones; polyether sulfones; polyamides; polyimides; polyanilines; polypyrroles; polybutylene terephthalate (PBT); polycarbonate (for example Makrolon® from Bayer AG); polyester acrylates; polyether acrylates; polyethylene; polyethylene thiophene; polyethylene naphthalates; polyethylene terephthalate (PET); polyethylene terephthalate glycol (PETG); polypropylene; polymethyl methacrylate (PMMA); polyphenylene oxide (PPO); polystyrenes (PS), polytetrafluoroethylene (PTFE); polytetrahydrofuran; polyethers (for example polyethylene glycol, polypropylene glycol); polyvinyl compounds, in particular polyvinyl chloride (PVC), PVC copolymers, PVdC, polyvinyl acetate as well as copolymers thereof, optionally partially hydrolyzed polyvinyl alcohol, polyvinyl acetals, polyvinyl acetates, polyvinyl pyrrolidone, polyvinyl ethers, polyvinyl acrylates and methacrylates in solution and as a dispersion as well as copolymers thereof, polyacrylates and polystyrene copolymers; polystyrene (modified or not to be shockproof); polyurethanes, uncrosslinked or crosslinked with isocyanates; polyurethane acrylate; styrene acrylic copolymers; styrene butadiene block copolymers (for example Styroflex® or Styrolux® from BASF AG, K-Resin™ from CPC); proteins, for example casein; SIS; triazine resin, bismaleimide triazine resin (BT), cyanate ester resin (CE), allylated polyphenylene ethers (APPE). Mixtures of two or more polymers may also form the matrix material.

Polymers particularly preferred as a matrix material are acrylates, acrylic resins, cellulose derivatives, methacrylates, methacrylic resins, melamine and amino resins, polyalkylenes, polyimides, epoxy resins, modified epoxy resins, for example bifunctional or polyfunctional Bisphenol A or Bisphenol F resins, epoxy-novolak resins, brominated epoxy resins, cycloaliphatic epoxy resins; aliphatic epoxy resins, glycidyl ethers, vinyl ethers and phenolic resins, polyurethanes, polyesters, polyvinyl acetals, polyvinyl acetates, polystyrenes, polystyrene copolymers, polystyrene acrylates, styrene butadiene block copolymers, alkenyl vinyl acetates and vinyl chloride copolymers, polyamides and copolymers thereof.

As a matrix material for the dispersion in the production of printed circuit boards, it is preferable to use thermally or radiation-curing resins, for example modified epoxy resins such as bifunctional or polyfunctional Bisphenol A or Bisphenol F resins, epoxy-novolak resins, brominated epoxy resins, cycloaliphatic epoxy resins; aliphatic epoxy resins, glycidyl ethers, cyanate esters, vinyl ethers, phenolic resins, polyimides, melamine resins and amino resins, polyurethanes, polyesters and cellulose derivatives

Expressed in terms of the total weight of the dry coating, the proportion of the organic binder components is preferably from 0.01 to 60 wt. %. The proportion is preferably from 0.1 to 45 wt. %, more preferably from 0.5 to 35 wt. %.

In order to be able to apply the dispersion containing the electrolessly and/or electrolytically coatable particles and the matrix material onto the support, a solvent or a solvent mixture may furthermore be added to the dispersion in order to adjust the viscosity of the dispersion suitable for the respective application method. Suitable solvents are, for example, aliphatic and aromatic hydrocarbons (for example n-octane, cyclohexane, toluene, xylene), alcohols (for example methanol, ethanol, 1-propanol, 2-propanol, 1-butanol, 2-butanol, amyl alcohol), polyvalent alcohols such as glycerol, ethylene glycol, propylene glycol, neopentyl glycol, alkyl esters (for example methyl acetate, ethyl acetate, propyl acetate, butyl acetate, isobutyl acetate, isopropyl acetate, 3-methyl butanol), alkoxy alcohols (for example methoxypropanol, methoxybutanol, ethoxypropanol), alkyl benzenes (for example ethyl benzene, isopropyl benzene), butyl glycol, dibutyl glycol, alkyl glycol acetates (for example butyl glycol acetate, dibutyl glycol acetate, propylene glycol methyl ether acetate), diacetone alcohol, diglycol dialkyl ethers, diglycol monoalkyl ethers, dipropylene glycol dialkyl ethers, dipropylene glycol monoalkyl ethers, diglycol alkyl ether acetates, dipropylene glycol alkyl ether acetate, dioxane, dipropylene glycol and ethers, diethylene glycol and ethers, DBE (dibasic esters), ethers (for example diethyl ether, tetrahydrofuran), ethylene chloride, ethylene glycol, ethylene glycol acetate, ethylene glycol dimethyl ester, cresol, lactones (for example butyrolactone), ketones (for example acetone, 2-butanone, cyclohexanone, methyl ethyl ketone (MEK), methyl isobutyl ketone (MIBK)), dimethyl glycol, methylene chloride, methylene glycol, methylene glycol acetate, methyl phenol (ortho-, meta-, para-cresol), pyrrolidones (for example N-methyl-2-pyrrolidone), propylene glycol, propylene carbonate, carbon tetrachloride, toluene, trimethylol propane (TMP), aromatic hydrocarbons and mixtures, aliphatic hydrocarbons and mixtures, alcoholic monoterpenes (for example terpineol), water and mixtures of two or more of these solvents.

Preferred solvents are alcohols (for example ethanol, 1-propanol, 2-propanol, butanol), alkoxyalcohols (for example methoxy propanol, ethoxy propanol, butyl glycol, dibutyl glycol), butyrolactone, diglycol dialkyl ethers, diglycol monoalkyl ethers, dipropylene glycol dialkyl ethers, dipropylene glycol monoalkyl ethers, esters (for example ethyl acetate, butyl acetate, butyl glycol acetate, dibutyl glycol acetate, diglycol alkyl ether acetates, dipropylene glycol alkyl ether acetates, DBE, propylene glycol methyl ether acetate), ethers (for example tetrahydrofuran), polyvalent alcohols such as glycerol, ethylene glycol, propylene glycol, neopentyl glycol, ketones (for example acetone, methyl ethyl ketone, methyl isobutyl ketone, cyclohexanone), hydrocarbons (for example cyclbhexane, ethyl benzene, toluene, xylene), N-methyl-2-pyrrolidone, water and mixtures thereof.

In the case of liquid matrix materials (for example liquid epoxy resins, acrylic esters), the respective viscosity may alternatively be adjusted via the temperature during application, or via a combination of a solvent and temperature.

The dispersion may furthermore contain a dispersant component. This consists of one or more dispersants.

In principle, all dispersants known to the person skilled in the art for application in dispersions and described in the prior art are suitable. Preferred dispersants are surfactants or surfactant mixtures, for example anionic, cationic, amphoteric or nonionic surfactants. Cationic and anionic surfactants are described, for example, in “Encyclopedia of Polymer Science and Technology”, J. Wiley & Sons (1966), Vol. 5, pp. 816-818, and in “Emulsion Polymerisation and Emulsion Polymers”, ed. P. Lovell and M. El-Asser, Wiley & Sons (1997), pp. 224-226. It is nevertheless also possible to use polymers known to the person skilled in the art having pigment-affine anchor groups as dispersants.

The dispersant may be used in the range of from 0.01 to 50 wt. %, expressed in terms of the total weight of the dispersion. The proportion is preferably from 0.1 to 25 wt. %, particularly preferably from 0.2 to 10 wt. %.

The dispersion according to the invention may furthermore contain a filler component. This may consist of one or more fillers. For instance, the filler component of the metallizable mass may contain fillers in fiber, layer or particle form, or mixtures thereof. These are preferably commercially available products, for example carbon and mineral fillers.

It is furthermore possible to use fillers or reinforcers such as glass powder, mineral fibers, whiskers, aluminum hydroxide, metal oxides such as aluminum oxide or iron oxide, mica, quartz powder, calcium carbonate, barium sulfate, titanium dioxide or wollastonite.

Other additives may furthermore be used, such as thixotropic agents, for example silica, silicates, for example aerosils or bentonites, or organic thixotropic agents and thickeners, for example polyacrylic acid, polyurethanes, hydrated castor oil, dyes, fatty acids, fatty acid amides, plasticizers, networking agents, defoaming agents, lubricants, desiccants, crosslinkers, photoinitiators, sequestrants, waxes, pigments, conductive polymer particles.

The proportion of the filler component is preferably from 0.01 to 50 wt. %, expressed in terms of the total weight of the dry coating. From 0.1 to 30 wt. % are further preferred, and from 0.3 to 20 wt. % are particularly preferred.

There may furthermore be processing auxiliaries and stabilizers in the dispersion according to the invention, such as UV stabilizers, lubricating agents, corrosion inhibitors and flame retardants. Their proportion is usually from 0.01 to 5 wt. %, expressed in terms of the total weight of the dispersion. The proportion is preferably from 0.05 to 3 wt. %.

If the electrolessly and/or electrolytically coatable particles in the dispersion on the support cannot themselves sufficiently absorb the energy of the energy source, for example the laser, absorbents may be added to the dispersion. Depending on the laser beam source used, it may be necessary to select different absorbents. In this case either the absorbent is added to the dispersion or an additional separate absorbent layer is applied between the support and the dispersion. In the latter case, the energy is absorbed locally in the absorption layer and transferred to the dispersion by thermal conduction.

Suitable absorbents for laser radiation have a high absorption in the range of the laser wavelength. In particular, absorbents which have a high absorption in the near infrared and in the longer-wave VIS range of the electromagnetic spectrum are suitable. Such absorbents are suitable in particular for absorbing the radiation of high-power solid-state lasers, for example Nd-YAG lasers or IR diode lasers. Examples of suitable absorbents for laser irradiation dyes absorbing strongly in the infrared spectral range, for example phthalocyanines, naphthalocyanines, cyanines, quinones, metal complex dyes, such as dithiolenes or photochromic dyes.

Other suitable absorbents are inorganic pigments, in particular intensely colored inorganic pigments such as chromium oxides, iron oxides, iron oxide hydrates or carbon, for example in the form of carbon black, graphite, graphenes or carbon nanotubes.

Finely divided types of carbon and finely divided lanthanum hexaboride (LaB₆) are particularly suitable as absorbents for laser radiation.

In general, from 0.005 to 20 wt. % of absorbent are used, expressed in terms of the weight of the electrolessly and/or electrolytically coatable particles in the dispersion. Preferably from 0.01 to 15 wt. % of absorbent and particularly preferably from 0.1 to 10 wt. % are used., expressed in terms of the weight of the electrolessly and/or electrolytically coatable particles in the dispersion.

The amount of absorbent added will be selected by the person skilled in the art according to the respectively desired properties of the dispersion layer. In this context, the person skilled in the art will furthermore take into account the fact that the added absorbents affect not only the rate and efficiency of the transfer of the dispersion by the laser, but also other properties such as for example the adhesion of the dispersion on the support, the curing or the electroless and/or electrolytic coatability of the base layer.

In the case of a separate absorption layer, in the most favorable case this consists of the absorbent and a thermally stable, optionally crosslinked material, so that it is not itself broken down under the effect of the laser light. In order to induce effective conversion of light energy into heat energy and achieve poor thermal conduction into the base layer, the absorption layer should be applied as thinly as possible and the absorbent should be present in as high as possible a concentration, without detrimentally affecting the layer properties, for example adhesion to the support. Suitable concentrations of the absorbent in the absorption layer are in this case at least 25 to 95 wt. %, from 50 to 85 wt. % being preferred.

The energy, which is needed in order to transfer the part of the dispersions containing the electrolessly and/or electrolytically coatable particles may be applied either on the site coated with the dispersion or on the opposite side from the dispersion, as a function of the laser used and/or the material from which the support is made. According to requirements, a combination of the two method variants may be used.

The parts of the dispersion may be transferred from the support onto the substrate either on one side or on both sides. The two sides may in this case be coated successively on both sides with the dispersion during the transfer, or on both sides simultaneously, for example by using two laser sources and two supports coated with the dispersion.

In order to increase productivity, it is possible to use more than one laser source.

In a preferred embodiment of the method according to the invention, the dispersion is applied onto the support before the dispersion is transferred from the support onto the substrate. The application is carried out, for example, by a coating method known to the person skilled in the art. Such coating methods are for example casting, for instance curtain casting, painting, doctor blading, brushing, spraying, immersion or the like. As an alternative, the dispersion containing the electrolessly and/or electrolytically coatable particles is printed onto the support by any printing method. The printing method, by which the dispersion is printed on, is for example a roller or sheet printing method, for example a screen printing, intaglio printing, flexographic printing, typography, pad printing, inkjet printing, offset printing or magnetographic printing method. Any other printing method known to the person skilled in the art may, however, also be used.

In a preferred embodiment, the dispersion is not fully dried and/or cured on the support, but instead is transferred in the wet state onto the substrate. This makes it possible, for example, to use a continuously operated printing mechanism in which the dispersion can be constantly replenished on the support. With this process management, a very high productivity can be achieved. Printing mechanisms which are continuously inked are known to the person skilled in the art, for example from DE-A 37 02 643. In order to prevent particles sedimenting from the dispersion, it is preferable for the dispersion to be stirred and/or pumped around in a storage container before application on the support. In order to adjust the viscosity of the dispersion, it is furthermore preferable that the storage container, in which the dispersion is contained, can be thermally regulated.

In a preferred embodiment, the support is configured as an endless belt transparent for the laser radiation in question, which is moved for example by inner-lying transport rollers. As an alternative, it is also possible to configure the support as a cylinder, in which case the cylinder may be moved via inner-lying transport rollers or is directly driven. The coating of the support with the dispersion containing the electrolessly and/or electrolytically coatable particles is then carried out for example by a method known to the person skilled in the art, for example with a roller or a roller system from a storage container in which the dispersion lies. By rotating the roller or the roller system, the dispersion is taken up and applied onto the support. By moving the support past the coating roller, a full-surface dispersion layer is applied onto the support. In order to transfer the dispersion onto the substrate, the laser beam source is arranged on the inside of the endless belt or of the cylinder. In order to transfer the dispersion, the laser beam is focused onto the dispersion layer, strikes the dispersion through the support which is transparent for it, and, at the position where it strikes the dispersion, it transfers the dispersion onto the substrate. Such an application mechanism is described, for example in DE-A 37 02 643. The dispersion is transferred, for example, by the energy of the laser beam evaporating the dispersion at least partially and the dispersion being transferred by the resulting gas bubble. The dispersion not transferred onto the substrate from the dispersion may be reused in a subsequent coating step.

The layer thickness of the base layer, which is transferred onto the substrate by means of the transfer by the laser, preferably varies in the range of between 0.01 and 50 μm, more preferably between 0.05 and 30 μm and particularly preferably between 0.1 and 20 μm. The base layer may be applied either surface-wide or in a structured manner.

Structured application of the dispersion onto the support is advantageous when particular structures are intended to be produced in large batch numbers, and the amount of dispersion which needs to be applied on the support is reduced by the structured application. More cost-effective production can be achieved in this way.

In order to obtain a mechanically stable, structured or full-surface base layer on the substrate, it is preferable for the dispersion, with which the structured or full-surface base layer is applied onto the substrate, to be cured at least partially after the application. As a function of the matrix material, for example, the curing is carried out by the action of heat, light (UV/Vis) and/or radiation, for example infrared radiation, electron radiation: gamma radiation, X-radiation, microwaves. In order to initiate the curing reaction, a suitable activator may need to be added. The curing may also be achieved by a combination of different methods, for example by a combination of UV radiation and heat. The curing methods may be combined simultaneously or successively. For example, the layer may first be only partially cured by UV radiation, so that the structures formed no longer flow apart. The layer may subsequently be cured by the action of heat. The heating may in this case take place directly after the UV curing and/or after the electrolytic metallization. After at least partially drying and/or curing the structure applied by laser energy onto the target substrate, in a preferred variant the electrically conductive particles may be at least partially exposed. In order to generate the continuous electrically conductive surface on the substrate, after the electrically conductive particles are exposed, at least one metal layer is formed by electroless and/or electrolytic coating on the structured or full-surface base layer. The coating may in this case be carried out using any method known to the person skilled in the art. Any conventional metal coating may moreover be applied using the coating method. In this case, the composition of the electrolyte solution, which is used for the coating, depends on the metal with which the electrically conductive structures on the substrate are intended to be coated. In principle, all metals which are nobler or equally noble as the least noble metal of the dispersion may be used for the electroless and/or electrolytic coating. Conventional metals which are deposited onto electrically conductive surfaces by electroless and/or electrolytic coating are, for example, gold, nickel, palladium, platinum, silver, tin, copper or chromium. The thicknesses of the one or more deposited layers lie in the conventional ranges known to the person skilled in the art.

Suitable electrolyte solutions, which are used for coating electrically conductive structures, are known to the person skilled in the art for example from Werner Jillek, Gustl Keller, Handbuch der Leiterplattentechnik [Handbook of printed circuit technology]. Eugen G. Leuze Verlag, 2003, volume 4, pages 332 to 352.

Since, after transferring the dispersion onto the substrate and at least partially drying or curing the matrix material, the electrolessly and/or electrolytically coatable particles mostly lie within the matrix so that a continuous electrically conductive surface has not yet been generated, it is necessary for the structured or full-surface base layer applied onto the substrate to be coated with an electrically conductive material. This is generally done by electroless and/or electrolytic coating.

In order to be able to electrolessly and/or electrolytically coat the structured or full-surface base layer on the substrate, it is first necessary to dry or cure the base layer at least partially. The structured or full-surface base layer is dried or cured according to conventional methods. For example, the matrix material may be cured chemically, for example by polymerization, polyaddition or polycondensation of the matrix material, for example using UV radiation, electron radiation, microwave radiation, IR radiation or temperature, or dried physically by evaporating the solvent. A combination of physical and chemical drying is also possible.

After the at least partial drying or curing, according to the invention the electrolessly and/or electrolytically coatable particles contained in the dispersion may be at least partially exposed, so as to directly obtain electrolessly and/or electrolytically coatable nucleation sites where the metal ions can be deposited during the subsequent electroless and/or electrolytic coating so as to form a metal layer. If the particles consist of materials which are readily oxidized, it may also be necessary to remove the oxide layer at least partially beforehand. Depending on the way in which the method is carried out, for example when using acidic electrolyte solutions, the removal of the oxide layer may already take place simultaneously as the metallization is carried out, without an additional process step being necessary.

The electrolessly and/or electrolytically coatable particles may be exposed either mechanically, for example by brushing, grinding, milling, sandblasting or blasting with supercritical carbon dioxide, physically, for example by heating, laser, UV light, corona or plasma discharge, or chemically. In the case of chemical exposure, it is preferable to use a chemical or chemical mixture which is compatible with the matrix material. In the case of chemical exposure, either the matrix material may be at least partially dissolved on the surface and washed away, for example by a solvent, or the chemical structure of the matrix material may be at least partially disrupted by means of suitable reagents so that the electrolessly and/or electrolytically coatable particles are exposed. Reagents which make the matrix material tumesce are also suitable for exposing the electrolessly and/or electrolytically coatable particles. The tumescence creates cavities which the metal ions to be deposited can enter from the electrolyte solution, so that a larger number of electrolessly and/or electrolytically coatable particles can be metallized. The bonding, homogeneity and continuity of the metal layer subsequently deposited electrolessly and/or electrolytically is significantly better than in the methods described in the prior art. The process rate of the metallization is also higher because of the larger number of exposed electrolessly and/or electrolytically coatable particles, so that additional cost advantages can be achieved.

If the matrix material is for example an epoxy resin, a modified epoxy resin, an epoxy-Novolak, a polyacrylate, ABS, a styrene-butadiene copolymer or a polyether, the electrolessly and/or electrolytically coatable particles are preferably exposed by using an oxidant. The oxidant breaks bonds of the matrix material, so that the binder can be dissolved and the particles can thereby be exposed. Suitable oxidants are, for example, manganates such as for example potassium permanganate, potassium manganate, sodium permanganate, sodium manganate, hydrogen peroxide, oxygen, oxygen in the presence of catalysts such as for example manganese salts, molybdenum salts, bismuth salts, tungsten salts and cobalt salts, ozone, vanadium pentoxide, selenium dioxide, ammonium polysulfide solution, sulfur in the presence of ammonia or amines, manganese dioxide, potassium ferrate, dichromate/sulfuric acid, chromic acid in sulfuric acid or in acetic acid or in acetic anhydride, nitric acid, hydroiodic acid, hydrobromic acid, pyridinium dichromate, chromic acid-pyridine complex, chromic acid anhydride, chromium(VI) oxide, periodic acid, lead tetraacetate, quinone, methylquinone, anthraquinone, bromine, chlorine, fluorine, iron(III) salt solutions, disulfate solutions, sodium percarbonate, salts of oxohalic acids such as for example chlorates or bromates or iodates, salts of perhalic acids such as for example sodium periodate or sodium perchlorate, sodium perborate, dichromates such as for example sodium dichromate, salts of persulfuric acids such as potassium peroxodisulfate, potassium peroxomonosulfate, pyridinium chlorochromate, salts of hypohalic acids, for example sodium hypochloride, dimethyl sulfoxide in the presence of electrophilic reagents, tert-butyl hydroperoxide, 3-chloroperbenzoate, 2,2-dimethylpropanal, Des-Martin periodinane, oxalyl chloride, urea hydrogen peroxide adduct, urea hydrogen peroxide, 2-iodoxybenzoic acid, potassium peroxomonosulfate, m-chloroperbenzoic acid, N-methylmorpholine-N-oxide, 2-methylprop-2-yl hydroperoxide, peracetic acid, pivaldehyde, osmium tetraoxide, oxone, ruthenium(III) and (IV) salts, oxygen in the presence of 2,2,6,6-tetramethylpiperidinyl-N-oxide, triacetoxiperiodinane, trifluoroperacetic acid, trimethyl acetaldehyde, ammonium nitrate. The temperature during the process may optionally be increased in order to improve the exposure process.

Preferred are manganates, for example potassium permanganate, potassium manganate, sodium permanganate, sodium manganate, hydrogen peroxide, N-methylmorpholine-N-oxide, percarbonates, for example sodium or potassium percarbonate, perborates, for example sodium or potassium perborate, persulfates, for example sodium or potassium persulfate, sodium, potassium and ammonium peroxodi- and monosulfates, sodium hydrochloride, urea hydrogen peroxide adducts, salts of oxohalic acids such as for example chlorates or bromates or iodates, salts of perhalic acids such as for example sodium periodate or sodium perchlorate, tetrabutylammonium peroxidisulfate, quinone, iron(III) salt solutions, vanadium pentoxide, pyridinium dichromate, hydrochloric acid, bromine, chlorine, dichromates.

Particularly preferred are potassium permanganate, potassium manganate, sodium permanganate, sodium manganate, hydrogen peroxide and its adducts, perborates, percarbonates, persulfates, peroxodisulfates, sodium hypochloride and perchlorates.

In order to expose the electrolessly and/or electrolytically coatable particles in a matrix material which contains for example ester structures such as polyester resins, polyester acrylates, polyether acrylates, polyester urethanes, it is preferable for example to use acidic or alkaline chemicals and/or chemical mixtures. Preferred acidic chemicals and/or chemical mixtures are, for example, concentrated or dilute acids such as hydrochloric acid, sulfuric acid, phosphoric acid or nitric acid. Organic acids such as formic acid or acetic acid may also be suitable, depending on the matrix material. Suitable alkaline chemicals and/or chemical mixtures are, for example, bases such as sodium hydroxide, potassium hydroxide, ammonium hydroxide or carbonates, for example sodium carbonate or calcium carbonate. The temperature during the process may optionally be increased in order to improve the exposure process.

Solvents may also be used to expose the electrolessly and/or electrolytically coatable particles in the matrix material. The solvent must be adapted to the matrix material, since the matrix material must dissolve in the solvent or be tumesced by the solvent. When using a solvent in which the matrix material dissolves, the base layer is brought in contact with the solvent only for a short time so that the upper layer of the matrix material is solvated and thereby dissolved. Preferred solvents are xylene, toluene, halogenated hydrocarbons, acetone, methyl ethyl ketone (MEK), methyl isobutyl ketone (MIBK), diethylene glycol monobutyl ether. The temperature during the dissolving process may optionally be increased in order to improve the dissolving behavior.

Furthermore, it is also possible to expose the electrolessly and/or electrolytically coatable particles by using a mechanical method. Suitable mechanical methods are, for example, brushing, grinding, polishing with an abrasive or pressure blasting with a water jet, sandblasting or blasting with supercritical carbon dioxide. The top layer of the cured, printed structured base layer is respectively removed by such a mechanical method. The electrolessly and/or electrolytically coatable particles contained in the matrix material are thereby exposed.

All abrasives known to the person skilled in the art may be used as abrasives for polishing. A suitable abrasive is, for example, pumice powder. In order to remove the top layer of the cured dispersion by pressure blasting with a water jet, the water jet preferably contains small solid particles, for example pumice powder (Al₂O₃) with an average particle size distribution of from 40 to 120 μm, preferably from 60 to 80 μm, as well as quartz powder (SiO₂) with a particle size>3 μm.

If the electrolessly and/or electrolytically coatable particles contain a material which can readily be oxidized, in a preferred method variant the oxide layer is at least partially removed before the metal layer is formed on the structured or full-surface base layer. The oxide layer may in this case be removed chemically and/or mechanically, for example. Suitable substances with which the base layer can be treated in order to chemically remove an oxide layer from the electrolessly and/or electrolytically coatable particles are, for example, acids such as concentrated or dilute sulfuric acid or concentrated or dilute hydrochloric acid, citric acid, phosphoric acid, amidosulfonic acid, formic acid, acetic acid.

Suitable mechanical methods for removing the oxide layer from the electrolessly and/or electrolytically coatable particles are generally the same as the mechanical methods for exposing the particles.

So that the dispersion which is applied onto the support bonds firmly to the support, in a preferred embodiment the latter is cleaned by a dry method, a wet chemical method and/or a mechanical method before applying the structured or full-surface base layer. By the wet chemical and mechanical methods, it is in particular also possible to roughen the surface of the support so that the dispersion bonds to it better. A suitable wet chemical method is, in particular, washing the support with acidic or alkaline reagents or with suitable solvents. Water may also be used in conjunction with ultrasound. Suitable acidic or alkaline reagents are, for example, hydrochloric acid, sulfuric acid or nitric acid, phosphoric acid, or sodium hydroxide, potassium hydroxide or carbonates such as potassium carbonate. Suitable solvents are the same as those which may be contained in the dispersion for applying the base layer. Preferred solvents are alcohols, ketones and hydrocarbons, which need to be selected as a function of the support material. The oxidants which have already been mentioned for the activation may also be used. As an alternative, an additional suitable bonding layer, a so-called primer, may be applied on the substrate by a coating method known to the person skilled in the art, before the dispersion is transferred by using the laser.

Mechanical methods with which the support can be cleaned before applying the structured or full-surface base layer are generally the same as those which may be used to expose the electrolessly and/or electrolytically coatable particles and to remove the oxide layer of the particles.

Dry cleaning methods in particular are suitable for removing dust and other particles which can affect the bonding of the dispersion on the support, and for roughening the surface. These are, for example, dust removal by means of brushes and/or deionized air, corona discharge or low-pressure plasma as well as particle removal by means of rolls and/or rollers, which are provided with an adhesive layer.

By corona discharge and low-pressure plasma, the surface tension of the substrate can be selectively increased, organic residues can be cleaned from the substrate surface, and therefore both the wetting with the dispersion and the bonding of the dispersion can be improved.

In order to improve the adhesion of the applied base layer on the substrate, according to requirements, the substrate may be provided with an additional bonding or adhesive layer by methods known to the person skilled in the art before the base layer is transferred.

Besides coating the substrate on one side, with the method according to the invention it is also possible to provide the support with an electrically conductive structured or full-surface base layer on its upper side and its lower side. With the aid of through-contacts, the structured or full-surface electrically conductive base layers on the upper side and the lower side of the support can be electrically connected to one another. For through-contacting, for example, a wall of a bore in the support is provided with an electrically conductive surface. In order to produce the through-contact, it is possible to form bores in the support, for example, onto the walls of which the dispersion that contains the electrolessly and/or electrolytically coatable particles is likewise deposited during the transfer. For a sufficiently thin support, for example a PET sheet, it is not necessary to coat the walls of the bores with the dispersion since, with a sufficiently long coating time, a metal layer also forms inside the bore during the electroless and/or electrolytic coating by the metal layers growing together into the bore from the upper and lower sides of the support. An electrical connection is thereby created between the electrically conductive structured or full-area surfaces on the upper and lower sides of the support. Besides the method according to the invention, it is also possible to use other methods known from the prior art for the production of bores and/or blind holes and their metallization.

In the case of thin supports, the boring may for example be carried out by slitting, punching or laser boring.

In order to coat the electrically conductive structured or full-area surface on the substrate, the latter is first sent to the bath containing the electrolyte solution. The substrate is then transported through the bath, the electrically conductive particles contained in the previously applied structured or full-surface base layer being contacted by at least one cathode in the case of electrolytic coating. Here, any suitable conventional cathode known to the person skilled in the art may be used. As long as the cathode contacts the structured or full-area surface, metal ions are deposited from the electrolyte solution to form a metal layer on the surface. For the contacting, it is also possible to provide auxiliary lines which are connected to the base layer. The contacting with the cathode then takes place via the auxiliary line.

Usually, a thin layer is formed immediately by electroless deposition on the base layer when it is immersed in the electrolyte solution.

If the base layer is self is not sufficiently conductive, for example when using carbon carbonyl-iron powder as electrolessly and/or electrolytically coatable particles, the conductivity required for the electrolytic coating is achieved by this electrolessly deposited layer.

A suitable device, in which the structured or full-surface electrically conductive base layer can be electrolytically coated, generally comprises at least one bath, one anode and one cathode, the bath containing an electrolyte solution containing at least one metal salt. Metal ions from the electrolyte solution are deposited on electrically conductive surfaces of the substrate to form a metal layer. To this end, the at least one cathode is brought in contact with the substrate's base layer to be coated, or with an auxiliary line which is in contact with the substrate's base layer to be coated, while the substrate is transported through the bath.

All electrolytic methods known to the person skilled in the art are suitable for the electrolytic coating in this case.

If auxiliary contacting lines are used for the electrolytic coating, these are generally produced in the same way as the base layer. The auxiliary contacting lines are likewise preferably dried and/or cured at least partially. After the curing, exposure of the electrolessly and/or electrolytically coatable particles contained on the surface may likewise be carried out for the auxiliary contacting lines. The auxiliary contacting lines are used, for example, so that even short, mutually insulated conductor tracks can be readily contacted. In a preferred embodiment, the auxiliary contacting lines are removed again after the electroless and/or electrolytic metallization. The removal may for example be carried out by laser ablation, i.e. by removal with a laser.

In order to achieve a larger layer thickness, the electrolytic coating device may, for example, be equipped with a device by which the substrate can be rotated. The rotation axis of the device, by which the substrate can be rotated, is in this case arranged perpendicularly to the substrate's surface to be coated. Electrically conductive structures which are initially wide and short as seen in the transport direction of the substrate, are aligned by the rotation so that they are narrow and long as seen in the transport direction after the rotation.

The layer thickness of the metal layer deposited on the electrically conductive structure by the method according to the invention depends on the contact time, which is given by the speed with which the substrate passes through the device and the number of cathodes positioned in series, as well as the current strength with which the device is operated. A longer contact time may be achieved, for example, by connecting a plurality of devices according to the invention in series in at least one bath.

In order to permit simultaneous coating of the upper and lower sides, for example two contacting rollers may respectively be arranged so that the substrate to be coated can be guided through between them while simultaneously being contacted from above and below, so that metal can be deposited on both sides.

When the intention is to coat flexible foils whose length exceeds the length of the bath—so-called endless foils which are first unwound from a roll, guided through the electrolytic coating device and then wound up again—they may for example also be guided through the bath in a zigzag shape or in the form of a meander around a plurality of electrolytic coating devices, which for example may then also be arranged above one another or next to one another.

The electrolytic coating device may, according to requirements, be equipped with any auxiliary device known to the person skilled in the art. Such auxiliary devices are, for example, pumps, filters, supply instruments for chemicals, winding and unwinding instruments etc.

All methods of treating the electrolyte solution known to the person skilled in the art may be used in order to shorten the maintenance intervals. Such treatment methods, for example, are also systems in which the electrolyte solution self-regenerates.

The device according to the invention may also be operated, for example, in the pulse method known from Werner Jillek, Gustl Keller, Handbuch der Leiterplattentechnik [Handbook of printed circuit technology], Eugen G. Leuze Verlag, volume 4, pages 192, 260, 349, 351, 352, 359.

After the electrolytic coating, the substrate may be processed further according to all steps known to the person skilled in the art. For example, existing electrolyte residues may be removed from the substrate by washing and/or the substrate may be dried.

The method according to the invention for producing electrically conductive, structured or full-area surfaces on a support may be operated in a continuous, semicontinuous or discontinuous mode. It is also possible for only individual steps of the method to be carried out continuously, while other steps are carried out discontinuously.

Besides producing a structured surface, with the method according to the invention it is also possible to transfer a plurality of layers successively onto the substrate. After having carried out the method in order to produce a first structured surface, for example, a structured or full-surface insulation layer may be applied by a printing method as described above. In this way, for example, it is possible to generate an insulator bridge over a conductor track, onto which a further conductor track can be applied when carrying out the method according to the invention again, so that an electrical contact is possible between conductor tracks running over one another is possible only at a predetermined points, at which the lower structured surface is not covered by insulation material.

The method according to the invention is suitable, for example, for the production of conductor tracks on printed circuit boards. Such printed circuit boards are, for example, those with multilayer inner and outer levels, micro-via-chip-on-boards, flexible and rigid printed circuit boards. These are for example installed in products such as computers, telephones, televisions, electrical automobile components, keyboards, radios, video, CD, CD-ROM and DVD players, game consoles, measuring and regulating equipment, sensors, electrical kitchen appliances, electrical toys etc.

Electrically conductive structures on flexible circuit supports may also be coated with the method according to the invention. Such flexible circuit supports are, for example, plastic films made of the aforementioned materials mentioned for the supports, onto which electrically conductive structures are printed. The method according to the invention is furthermore suitable for producing RFID antennas, transponder antennas or other antenna structures, chip card modules, flat cables, seat heaters, foil conductors, conductor tracks in solar cells or in LCD/plasma display screens, capacitors, foil capacitors, resistors, convectors, electrical fuses or for producing electrically coated products in any form, for example polymer supports clad with metal on one or two sides with a defined layer thickness, 3D molded interconnected devices or for producing decorative or functional surfaces on products, which are used for example for shielding electromagnetic radiation, for thermal conduction or as packaging. It is furthermore possible to produce contact points or contact pads or interconnections on an integrated electronic component.

The production of integrated circuits, resistive, capacitive or inductive elements, diodes, transistors, sensors, actuators, optical components and receiver/transmission devices is also possible with the method according to the invention.

It is furthermore possible to produce antennas with contacts for organic electronic components, as well as coatings on surfaces consisting of electrically nonconductive material for electromagnetic shielding.

Use is furthermore possible in the context of flow fields of bipolar plates for application in fuel cells.

It is furthermore possible to produce a full-area or structured electrically conductive layer for subsequent decor metallization of shaped articles made of the aforementioned electrically nonconductive substrate.

The application range of the method according to the invention allows inexpensive production of metallized, even nonconductive substrates, particularly for use as switches and sensors, gas barriers or decorative parts, in particular decorative parts for the motor vehicle, sanitary, toy, household and office sectors, and packaging as well as foils. The invention may also be applied in the field of security printing for banknotes, credit cards, identity documents etc. Textiles may be electrically and magnetically functionalized with the aid of the method according to the invention (antennas, transmitters, RFID and transponder antennas, sensors, heating elements, antistatic (even for plastics), shielding etc.).

It is furthermore possible to produce thin metal foils, or polymer supports clad on one or two sides, or metallized plastic surfaces.

The method according to the invention may likewise be used for the metallization of holes, vias, blind holes etc., for example in printed circuit boards, RFID antennas or transponder antennas, flat cables, foil conductors with a view to through-contacting the upper and lower sides. This also applies when other substrates are used. The metallized articles produced according to the invention—if they comprise magnetizable metals—may also be employed in the field of magnetizable functional parts such as magnetic tables, magnetic games, magnetic surfaces for example on refrigerator doors. They may also be employed in fields in which good thermal conductivity is advantageous, for example in foils for seat heaters, as well as insulation materials.

Preferred uses of the surfaces metallized according to the invention are those in which the products produced in this way are used as printed circuit boards, RFID antennas, transponder antennas, seat heaters, flat cables, contactless chip cards, thin metal foils or polymer supports clad on one or two sides, foil conductors, conductor tracks in solar cells or in LCD/plasma screens, integrated circuits, resistive, capacitive or inductive elements, diodes, transistors, sensors, actuators, optical components, receiver-transmission devices, or as decorative application, for example for packaging materials.

1. A method for producing electrically conductive surfaces on a nonconductive substrate, comprising the following steps:
a) transferring a dispersion containing electrolessly and/or electrolytically coatable particles from a support onto the substrate by irradiating the support with a laser,
b) at least partially drying and/or curing the dispersion transferred onto the substrate, so as to form a base layer,
c) electrolessly and/or electrolytically coating the base layer.

2. The method as claimed in claim 1, wherein the dispersion is applied onto the support before the transfer in step a).

3. The method as claimed in claim 2, wherein the dispersion is applied onto the support by a coating method, in particular by a printing, casting, rolling or spraying method.

4. The method as claimed in claim 1, wherein the dispersion is stirred and/or pumped around and/or thermally regulated in a storage container before application.

5. The method as claimed in claim 1, wherein the particles contained on the surface of the base layer are exposed after the at least partial drying and/or curing in step b).

6. The method as claimed in claim 5, wherein the particles contained on the surface of the base layer are exposed by removing matrix material of the base layer.

7. The method as claimed in claim 5, wherein the particles contained on the surface of the base layer are exposed chemically, physically or mechanically.

8. The method as claimed in claim 1, wherein the laser generates a laser beam with a wavelength in the range of from 150 to 10,600 nm, preferably in the range of from 600 to 10,600 nm.

9. The method as claimed in claim 1, wherein the laser is a solid state laser, a fiber laser, a diode laser, a gas laser or an excimer laser.

10. The method as claimed in claim 1, wherein the electrolessly and/or electrolytically coatable particles contain at least one metal and/or carbon.

11. The method as claimed in claim 10, wherein the metal is selected from the group consisting of iron, nickel, silver, zinc, tin and copper.

12. The method as claimed in claim 10, wherein at least some of the electrolessly and/or electrolytically coatable particles are carbonyl-iron powder.

13. The method as claimed in claim 1, wherein the electrolessly and/or electrolytically coatable particles have different particle geometries.

14. The method as claimed in claim 1, wherein the dispersion contains an absorbent.

15. The method as claimed in claim 14, wherein the absorbent is carbon or lanthanum hexaboride.

16. The method as claimed in claim 1, wherein an oxide layer which may be present is removed from the electrolessly and/or electrolytically coatable particles before the electroless and/or electrolytic coating of the base layer.

17. The method as claimed in claim 1, wherein the substrate is cleaned by a dry chemical, wet chemical and/or mechanical method before the dispersion is transferred in step a).

18. The method as claimed in claim 1, wherein the dispersion is transferred onto the upper side and the lower side of the substrate in order to form the base layer.

19. The method as claimed in claim 17, wherein the base layers on the upper side and the lower side of the substrate are connected together by through-contacting.

20. The method as claimed in claim 1 wherein the base layer is connected for electrolytic coating to auxiliary contacting lines which are electrically conductively connected to a cathode.

21. The method as claimed in claim 1, wherein the support is a rigid or flexible plastic or glass transparent for the laser radiation being used.

22. The method as claimed in claim 1 for producing conductor tracks on printed circuit boards, RFID antennas, transponder antennas or other antenna structures, chip card modules, flat cables, seat heaters, foil conductors, conductor tracks in solar cells or in LCD/plasma screens, 3D molded interconnected devices, integrated circuits, resistive, capacitive or inductive elements, diodes, transistors, sensors, actuators, optical components, receiver/transmission devices, decorative or functional surfaces on products, which are used for shielding electromagnetic radiation, for thermal conduction or as packaging, thin metal foils or polymer supports clad on one or two sides, or for producing electrolytically coated products in any form.
